(19) United States
(12) Patent Application Publication
(10) Pub. No.: US 2025/0157702 A1
(43) Pub. Date: May 15, 2025

(54) ELECTRONIC COMPONENT AND FILM FORMING METHOD

(71) Applicant: Murata Manufacturing Co., Ltd., Nagaokakyo-shi (JP)

(72) Inventors: Mitsuru NAKANO, Nagaokakyo-shi (JP); Hiroshi SHIRAKI, Nagaokakyo-shi (JP)

(73) Assignee: Murata Manufacturing Co., Ltd., Nagaokakyo-shi (JP)

(21) Appl. No.: 19/021,348

(22) Filed: Jan. 15, 2025

Related U.S. Application Data
(63) Continuation of application No. PCT/JP2023/044630, filed on Dec. 13, 2023.

(30) Foreign Application Priority Data
May 17, 2023 (JP) 2023-081645

(51) Int. Cl. H01C 7/04; H01C 1/14; H01C 17/00

(52) U.S. Cl. CPC H01C 7/04; H01C 1/1413; H01C 17/00

(57) ABSTRACT

An electronic component includes a base body, an alumina film, an internal electrode, and an external electrode. A region of the alumina film excluding a range of 10% of a thickness of the alumina film from a boundary surface with the base body toward an outer surface of the alumina film in the alumina film and a range of 10% of the thickness of the alumina film from the outer surface of the alumina film toward the base body in the alumina film is a specific region. Each region obtained by dividing the specific region into 10 equal parts in a thickness direction of the alumina film is a divided region, an atomic percentage of the specific atom in each divided region is 0.5 times or more and 1.5 times or less an atomic percentage of the same specific atom in the entire specific region.

### CROSS-REFERENCE TO RELATED APPLICATIONS

This application is a continuation application of PCT International Application No. PCT/JP2023/044630 filed on Dec. 13, 2023, designating the United States of America, which is based on and claims priority to Japanese Patent Application No. 2023-081645 filed on May 17, 2023. The entire disclosures of the above-identified applications, including the specifications, drawings, and claims are incorporated herein by reference in their entirety.

### BACKGROUND

A typical electric component includes a base body, an internal electrode, an external electrode, and a protective film. The internal electrode is located inside the base body. The protective film covers the outer surface of the base body. The protective film is an alumina film containing aluminum atoms and oxygen atoms. The protective film is formed by high-frequency sputtering. The external electrode is stacked on the outer surface of the protective film. The external electrode is electrically connected to the internal electrode. The external electrode includes a silver powder, an organic binder, and a glass frit.

### SUMMARY

### Problems to be Solved

As recognized by the present inventors, in the typical electric components described above, the protective film is made of what is called an inorganic component. On the other hand, the external electrode stacked on the protective film contains not only an inorganic component but also an organic component. When the external electrode contains an organic component as described above, it is difficult to improve the adhesion of the external electrode to the protective film.

### SOLUTIONS TO THE PROBLEMS

An electronic component including: a base body; an alumina film covering an outer surface of the base body and containing an aluminum atom and an oxygen atom; an internal electrode located inside the base body; and an external electrode electrically connected to the internal electrode and located on an outer surface of the alumina film, in which the alumina film contains one or more specific atoms selected from a carbon atom and a hydrogen atom, and where a region of the alumina film excluding a range of 10% of a thickness of the alumina film from a boundary surface with the base body toward the outer surface of the alumina film and a range of 10% of the thickness of the alumina film from the outer surface of the alumina film toward the base body is defined as a specific region and each region obtained by dividing the specific region into 10 equal parts in a thickness direction of the alumina film is defined as a divided region, an atomic percentage of the specific atom in each divided region is 0.5 times or more and 1.5 times or less an atomic percentage of the specific atom of the same kind in the entire specific region.

An aspect of the present disclosure is a film forming method for forming an alumina film on an outer surface of a base body, the film forming method including: a charging step of charging the base body into a first chamber that is capable of heating an internal atmosphere; a misting step of forming a raw material that is liquid and contains an aluminum atom and an oxygen atom into mist-like with an ultrasonic wave in a second chamber; a supply step of supplying the mist-like raw material from an inside of the second chamber into the first chamber together with a carrier gas; and a heating step of heating the atmosphere inside the first chamber while performing the supply step, in which the raw material further contains one or more selected from a carbon atom and a hydrogen atom.

### Advantageous Effects

Even when the external electrode contains an organic component, adhesion between the alumina film and the external electrode on the alumina film can be secured.

### BRIEF EXPLANATION OF DRAWINGS

FIG. 1 is a perspective view of an electronic component.

FIG. 2 is a side view of the electronic component.

FIG. 3 is a sectional view taken along line 3-3 in FIG. 2.

FIG. 4 is an explanatory diagram illustrating a method for manufacturing an electronic component.

FIG. 5 is an explanatory diagram illustrating the method for manufacturing an electronic component.

FIG. 6 is an explanatory diagram illustrating the method for manufacturing an electronic component.

FIG. 7 is an explanatory diagram illustrating the method for manufacturing an electronic component.

FIG. 8 is a table showing composition analysis results for each sample piece.

FIG. 9 is a graph showing composition analysis results for a first sample piece.

FIG. 10 is a graph showing composition analysis results for a second sample piece.

FIG. 11 is a graph showing composition analysis results for a third sample piece.

### DETAILED DESCRIPTION

### Exemplary Embodiment of Electronic Component

Hereinafter, an exemplary embodiment of the electronic component will be described with reference to the drawings. In the drawings, sometimes a component is illustrated while enlarged for the sake of easy understanding. In some cases, the dimension ratio of a component differs from an actual dimension ratio or a dimension ratio in another drawing.

### <Electronic Component>

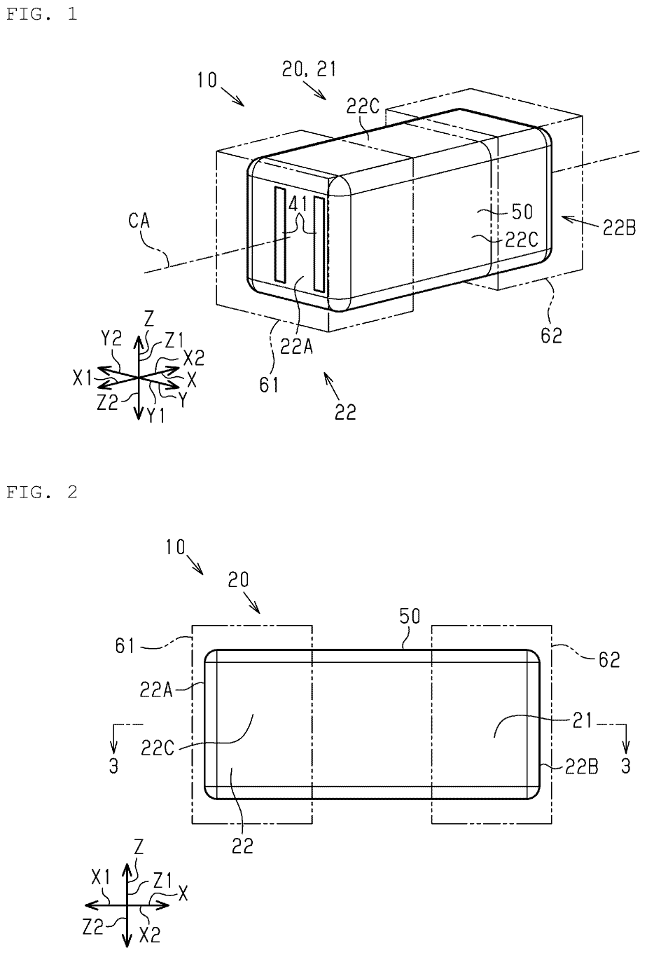

As shown in FIG. 1, an electronic component 10 is, for example, a surface mount negative characteristic thermistor component to be mounted on a circuit board or the like. It is to be noted that the negative characteristic thermistor component has a characteristic that the resistance value is decreased as the temperature is increased. The electronic component 10 includes a base body 20. The base body 20 has a substantially quadrangular prism shape and has a central axis CA. Hereinafter, an axis extending along the central axis CA is referred to as a first axis X. One of the axes orthogonal to the first axis X is defined as a second axis Y. Further, an axis that is orthogonal to both the first axis X and the second axis Y is defined as a third axis Z. In addition, one of the directions along the first axis X is defined as a first positive direction X1, and the direction opposite to the first positive direction X1, of the directions along the first axis X, is defined as a first negative direction X2. In addition, one of the directions along the second axis Y is defined as a second positive direction Y1, and the direction opposite to the second positive direction Y1, of the directions along the second axis Y, is defined as a second negative direction Y2. Further, one of the directions along the third axis Z is defined as a third positive direction Z1, and a direction opposite to the third positive direction 1 among the directions along the third axis Z is defined as a third negative direction Z2.

An outer surface 21 of the base body 20 has six flat faces 22. The term “face” or “surface” of the base body 20 as used herein refers to a part that can be observed as a surface when the entire base body 20 is observed. More specifically, for example, if there are such minute irregularities or steps that fail to be found unless a part of the base body 20 is enlarged and observed with a microscope or the like, the face is expressed as a flat face or a curved face. The six flat faces 22 face in different directions. The six flat faces 22 are roughly divided into a first end surface 22A that faces in the first positive direction X1, a second end surface 22B that faces in the first negative direction X2, and four side surfaces 22C. The four side surfaces 22C are a surface facing the third positive direction 21, a surface facing the third negative direction 22, a surface facing the second positive direction Y1, and a surface facing the second negative direction Y2, respectively.

In the outer surface 21 of the base body 20, a boundary portion between two adjacent flat faces 22 and a boundary portion between three adjacent flat faces 22 are curved surfaces. That is, corners of the base body 20 are what is called round chamfered.

As illustrated in FIG. 2, the base body 20 has a dimension in the direction along the first axis X larger than a dimension in the direction along the third axis Z. Furthermore, as illustrated in FIG. 1, in the base body 20, the dimension in the direction along the first axis X is larger than the dimension in the direction along the second axis Y. The material of the base body 20 is a semiconductor. Specifically, the material of the base body 20 is a ceramic obtained by firing a metal oxide containing at least one of Mn, Fe, Ni, Co, Ti, Ba, Al, and Zn as a component.

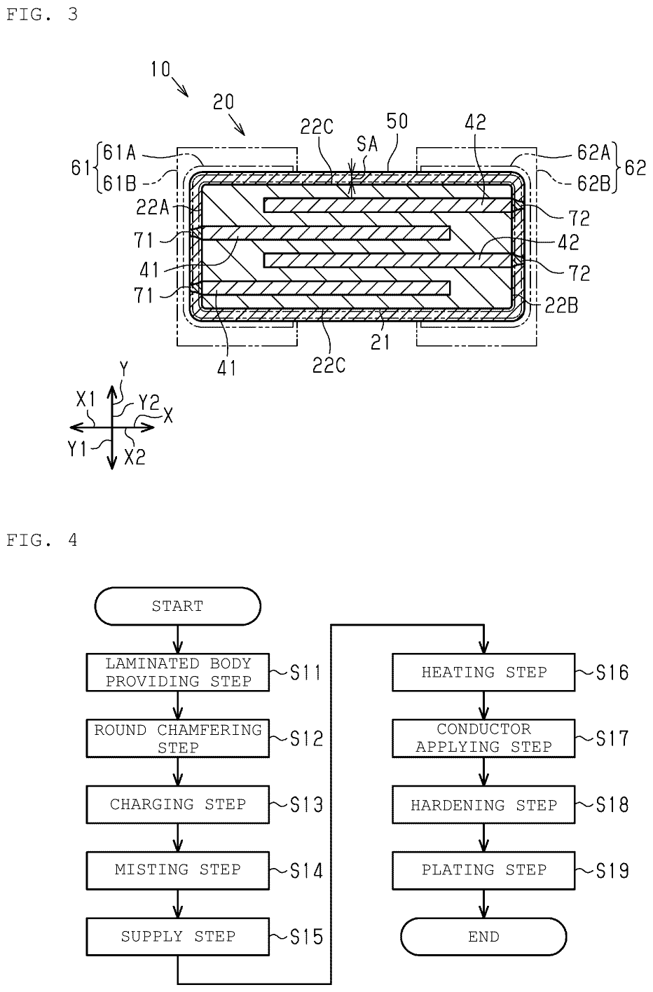

As shown in FIG. 3, the electronic component 10 includes two first internal electrodes 41 and two second internal electrodes 42. The first internal electrodes 41 and the second internal electrodes 42 are located inside the base body 20.

The material of the first internal electrode 41 is a conductive material. For example, the material of the first internal electrode 41 is palladium. The material of the second internal electrode 42 is the same as the material of the first internal electrode 41.

The first internal electrode 41 has a rectangular plate shape. The first internal electrode 41 has a main surface orthogonal to the second axis Y. The second internal electrode 42 has the same rectangular plate shape as the first internal electrode 41. A main surface of the second internal electrode 42 is orthogonal to the second axis Y, as with the first internal electrode 41.

The dimension of the first internal electrode 41 in the direction along the first axis X is smaller than the dimension of the base body 20 in the direction along the first axis X. As illustrated in FIG. 1, the dimension of the first internal electrode 41 in the direction along the third axis Z is approximately ⅔ of the dimension of the base body 20 in the direction along the third axis Z. The dimension of the second internal electrode 42 in each of the directions is the same as that of the first internal electrode 41.

As shown in FIG. 3, the first internal electrodes 41 and the second internal electrodes 42 are located in a staggered manner in the direction along the second axis Y. More specifically, the four internal electrodes in total are arranged alternately in the order of the first internal electrode 41, the second internal electrode 42, the first internal electrode 41, and the second internal electrode 42 toward the second negative direction Y2 from the side surface 22C that faces in the second positive direction Y1. In this exemplary embodiment, the distances between the respective internal electrodes in the direction along the second axis Y are equal to each other.

As illustrated in FIG. 1, the two first internal electrodes 41 and the two second internal electrodes 42 are both located at the center of the base body 20 in the direction along the third axis Z. On the other hand, as illustrated in FIG. 3, the first internal electrodes 41 are located deviated to the first positive direction X1. The second internal electrodes 42 are located deviated to the first negative direction X2.

Specifically, the end of the first internal electrode 41 on the first positive direction X1 side coincides with the end of the base body 20 on the first positive direction X1 side. The end of the first internal electrode 41 on the first negative direction X2 side is located inside the base body 20 and does not reach the end of the base body 20 on the first negative direction X2 side. On the other hand, the end of the second internal electrode 42 on the first negative direction X2 side coincides with the end of the base body 20 on the first negative direction X2 side. The end of the second internal electrode 42 on the first positive direction X1 side is located inside the base body 20 and does not reach the end of the base body 20 on the first positive direction X1 side.

As illustrated in FIG. 3, the electronic component 10 includes an alumina film 50. The alumina film 50 covers the outer surface 21 of the base body 20. According to the present exemplary embodiment, the alumina film 50 covers the whole region of the outer surface 21 of the base body 20. In the present exemplary embodiment, the alumina film 50 indicates that the main component of the film is alumina. Specifically, the alumina film 50 is a film in which the total of the atomic percentages of the aluminum atoms and the oxygen atoms contained in the film is 80% or more.

The electronic component 10 includes a first external electrode 61 and a second external electrode 62. The first external electrode 61 is located on the outer surface of the alumina film 50. The first external electrode 61 includes a first underlying electrode 61A and a first metal layer 61B. The first underlying electrode 61A is stacked on the alumina film 50 in a part including the first end surface 22A in the outer surface 21 of the base body 20. The first underlying electrode 61A is a five-face electrode that covers the first end surface 22A of the base body 20 and parts of the four side surfaces 22C thereof in the first positive direction X1. According to this exemplary embodiment, the material of the first underlying electrode 61A is a mixture of copper, glass, and an organic resin. Therefore, the first underlying electrode 61A is a sintered body containing an organic component.

As shown in FIG. 3, the first metal layer 61B covers the first underlying electrode 61A from the outside. Thus, the first metal layer 61B is stacked on the first underlying electrode 61A. In addition, a part of the first metal layer 61B is protruded from the first underlying electrode 61A. That is, a part of the outer edge of the first metal layer 61B directly covers the alumina film 50 without the first underlying electrode 61A interposed therebetween. Although not shown in the drawing, the first metal layer 61B has a two-layer structure of a nickel layer and a tin layer in this order from the first underlying electrode 61A side.

The second external electrode 62 includes a second underlying electrode 62A and a second metal layer 62B. The second underlying electrode 62A is stacked on the alumina film 50 in a part including the second end surface 22B in the outer surface 21 of the base body 20. The second underlying electrode 62A is a five-face electrode that covers the second end surface 22B of the base body 20 and parts of the four side surfaces 22C thereof in the first negative direction X2. According to this exemplary embodiment, the material of the second underlying electrode 62A is the same as the material of the first external electrode 61, and is a mixture of copper, glass, and an organic resin. Therefore, as with the first underlying electrode 61A, the second underlying electrode 62A is a sintered body containing an organic component.

The second metal layer 62B covers the second underlying electrode 62A from the outside. Thus, the second metal layer 62B is stacked on the second underlying electrode 62A. In addition, a part of the second metal layer 62B is protruded from the second underlying electrode 62A. That is, a part of the outer edge of the second metal layer 62B directly covers the alumina film 50 without the second underlying electrode 62A interposed therebetween. Although not shown in the drawing, the second metal layer 62B has, as with the first metal layer 61B, a two-layer structure of a nickel layer and a tin layer in this order from the second underlying electrode 62A.

The second external electrode 62 does not reach the first external electrode 61 on the side surface 22C, and is disposed away from the first external electrode 61 in the direction along the first axis X. On the side surface 22C of the base body 20, the first external electrode 61 and the second external electrode 62 are not stacked and the alumina film 50 is exposed in the central portion in the direction along the first axis X. In FIGS. 1 to 3, the first external electrode 61 and the second external electrode 62 are indicated by dot-dot-dash lines.

The first external electrode 61 and the end of the first internal electrode 41 on the first positive direction X1 side are connected via a first penetrating portion 71 penetrating the alumina film 50. Thus, the first external electrode 61 is electrically connected to the first internal electrode 41. Although details will be described later, the first penetrating portion 71 is formed such that palladium constituting the first internal electrode 41 extends to the first external electrode 61 side in the manufacturing process of the electronic component 10.

The second external electrode 62 and the end of the second internal electrode 42 on the first negative direction X2 side are connected via a second penetrating portion 72 penetrating the alumina film 50. Thus, the second external electrode 62 is electrically connected to the second internal electrode 42. Similarly to the first penetrating portion 71, the second penetrating portion 72 is also formed such that palladium constituting the second internal electrode 42 extends to the second external electrode 62 side in the manufacturing process of the electronic component 10. In FIG. 3, the first internal electrode 41 and the first penetrating portion 71 are illustrated as separate members having a boundary; however, actually, there is no clear boundary therebetween. In this respect, the same applies to the second penetrating portion 72. In FIG. 1, illustration of the first penetrating portion 71 is omitted.

### <Alumina Film>

As described above, the alumina film 50 contains aluminum atoms and oxygen atoms. Furthermore, the alumina film 50 contains both carbon atoms and hydrogen atoms as specific atoms in addition to aluminum atoms and oxygen atoms. It is sufficient that the alumina film 50 contains one or more selected from carbon atoms and hydrogen atoms as specific atoms.

For example, the average value of the thickness of the alumina film 50 is 0.05 μm or more and 2.0 μm or less. The thickness of the alumina film 50 is the shortest distance from the boundary surface of the alumina film 50 with the base body 20 to the outer surface of the alumina film 50. The average value of the thickness of the alumina film 50 is calculated as follows. First, an arbitrary section of the base body 20 is photographed with an electron microscope. Next, a range in a direction along the outer surface of the alumina film 50 is specified for the photographed image. In this range, the sectional area of the alumina film 50 is calculated by image processing in a measurement range of at least 5 μm or more. Then, the calculated sectional area of the alumina film 50 in the measurement range is divided by the length that is the measurement range to calculate the thickness of the alumina film 50. This is taken as the average value of the thickness of the alumina film 50.

Here, in the alumina film 50, a region excluding a portion serving as a boundary with another substance is defined as a specific region SA. Specifically, the specific region SA is a region excluding a range of 10% of the thickness of the alumina film 50 from the boundary surface with the base body 20 toward the outer surface of the alumina film 50 in the alumina film 50 and a range of 10% of the thickness of the alumina film 50 from the outer surface of the alumina film 50 toward the base body 20 in the alumina film 50. That is, if the thickness of the alumina film 50 is 200 nm, the specific region SA is a region of 160 nm at the center of the alumina film 50 excluding the range of 20 nm from the boundary surface with the base body 20 toward the outer surface of the alumina film 50 and the range of 20 nm from the outer surface of the alumina film 50 toward the base body 20. In the present exemplary embodiment, a position where an atom that is not included in the alumina film 50 and is included in the base body 20 is detected is defined as the boundary between the alumina film 50 and the base body 20.

The atomic percentage of aluminum atoms in the entire specific region SA is 30 at % or more and 40 at % or less. The atomic percentage of oxygen atoms in the entire specific region SA is 50 at % or more and 60 at % or less. The atomic percentage of hydrogen atoms in the entire specific region SA is 3.0 at % or more and 15.0 at % or less. The atomic percentage of carbon atoms in the entire specific region SA is 0.3 at % or more and 3.0 at % or less. The atomic percentage of each atom in the entire specific region SA is a value measured by composition analysis using Rutherford backscattering spectrometry (RBS).

Here, each region obtained by dividing the specific region SA into 10 equal parts in the thickness direction of the alumina film 50 is defined as a divided region. If the thickness of the alumina film 50 is 200 nm, each divided region is a region obtained by division of every 16 nm in the thickness direction of the alumina film 50. The atomic percentage of the specific atoms in each of the divided regions is 0.5 times or more and 1.5 times or less the atomic percentage of the same kind of specific atoms in the entire specific region SA.

Specifically, the atomic percentage of carbon atoms in each of the divided regions is 0.5 times or more and 1.5 times or less the atomic percentage of carbon atoms in the entire specific region SA. If the atomic percentage of carbon atoms in the entire specific region SA is 1.6 at %, in the present exemplary embodiment, the atomic percentage of carbon atoms in each divided region is 0.8 at % or more and 2.4 at % or less. When the variation in the atomic percentage of carbon atoms is within the above range in each of the divided regions, it can be said that the value of the atomic percentage of carbon atoms is substantially constant in the thickness direction in the specific region SA.

The atomic percentage of hydrogen atoms in each of the divided regions is 0.5 times or more and 1.5 times or less the atomic percentage of hydrogen atoms in the entire specific region SA. If the atomic percentage of hydrogen atoms in the entire specific region SA is 8 at %, the atomic percentage of carbon atoms in each divided region is 4 at % or more and 12 at % or less. When the variation in the atomic percentage of hydrogen atoms is within the above range in each of the divided regions, it can be said that the value of the atomic percentage of hydrogen atoms is substantially constant in the thickness direction in the specific region SA.

In addition, the atomic percentage of aluminum atoms and the atomic percentage of oxygen atoms in each of the divided regions are both minus 5 at % or more and plus 5 at % or less of the atomic percentage of the same kind of atoms in the entire specific region SA. Specifically, if the atomic percentage of aluminum atoms in the entire specific region SA is 35 at %, the atomic percentage of aluminum atoms in each divided region falls within the range of 30 at % or more and 40 at % or less. If the atomic percentage of oxygen atoms in the entire specific region SA is 55 at %, the atomic percentage of oxygen atoms in each divided region falls within the range of 50 at % or more and 60 at % or less. As described above, when the variation in the atomic percentages of aluminum atoms and oxygen atoms are within the above ranges in each of the divided regions, it can be said that the values of the atomic percentages of aluminum atoms and oxygen atoms are substantially constant in the thickness direction in the specific region SA.

### <Method for Manufacturing Electronic Component>

Next, the method for manufacturing the electronic component 10 will be described.

As shown in FIG. 4, the method for manufacturing the electronic component 10 includes a laminated body providing step S11, a round chamfering step S12, a charging step S13, a misting step S14, a supply step S15, and a heating step S16. The method for manufacturing the electronic component 10 further includes a conductor applying step S17, a hardening step S18, and a plating step S19.

First, in forming the base body 20, a laminated body is prepared in the laminated body providing step S11. The laminated body in this stage is in a state before round chamfering, and has a rectangular parallelepiped shape having the six flat faces 22. For example, first, a plurality of ceramic sheets to be the base body 20 are provided. Each of the sheets has a thin plate shape. A conductive paste to be the first internal electrode 41 is stacked on the sheet. A ceramic sheet to be the base body 20 is stacked on the laminated paste. A conductive paste to be the second internal electrode 42 is stacked on the sheet. In this manner, the ceramic sheet and the conductive paste are stacked. Then, the stacked sheets are subjected to pressure bonding in the stacking direction by means such as die pressing. Thereafter, the sheets subjected to the pressure bonding are cut into a predetermined size to form an unfired laminated body. Thereafter, the unfired laminated body is fired at a high temperature to provide a laminated body.

Next, the round chamfering step S12 is performed. In the round chamfering step S12, the laminated body provided in the laminated body providing step S11 is round chamfered. By this step, the base body 20 in which the corner portion is round chamfered is obtained.

Next, the charging step S13 to the heating step S16 are sequentially performed. A film forming apparatus 100 is used from the charging step S13 to the heating step S16.

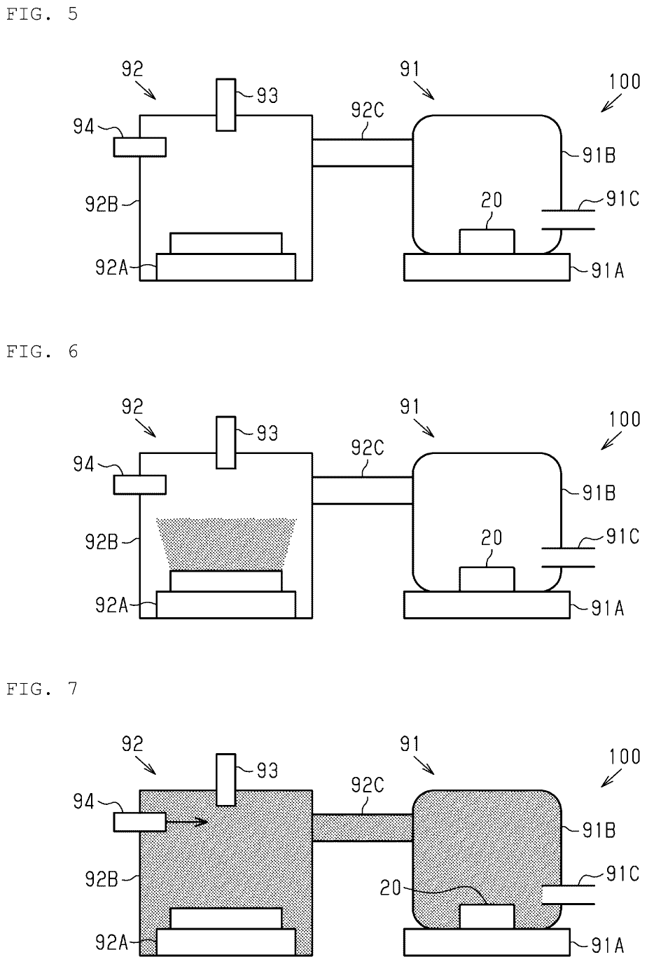

As illustrated in FIG. 5, the film forming apparatus 100 includes a first chamber 91. The first chamber 91 can heat the internal atmosphere. Specifically, the first chamber 91 includes a heater 91A, a container main body 91B, and a discharge passage 91C. The heater 91A is located at the bottom of the container main body 91B. By driving the heater 91A, the atmosphere in the container main body 91B is heated. The discharge passage 91C is connected to the container main body 91B. The inside of the container main body 91B communicates with the outside through the discharge passage 91C.

The film forming apparatus 100 includes a second chamber 92, a liquid supply nozzle 93, and a gas supply nozzle 94. The second chamber 92 includes an ultrasonic wave generator 92A, a container main body 92B, and a communication passage 92C. The ultrasonic wave generator 92A is located at the bottom of the container main body 92B. By driving the ultrasonic wave generator 92A, the liquid supplied into the container main body 92B can be made into a mist-like. The communication passage 92C is connected to the container main body 91B of the first chamber 91 and the container main body 92B of the second chamber 92. That is, the inside of the container main body 92B of the second chamber 92 communicates with the inside of the container main body 91B of the first chamber 91 via the communication passage 92C. The liquid supply nozzle 93 can supply a liquid raw material into the container main body 92B. The gas supply nozzle 94 can supply a carrier gas into the container main body 92B.

As shown in FIG. 4, the charging step S13 is performed. As illustrated in FIG. 5, in the charging step S13, the base body 20 is charged into the first chamber 91 of the film forming apparatus 100. Then, by driving the heater 91A of the first chamber 91, the atmosphere in the first chamber 91 is heated.

Next, the misting step S14 is performed. As illustrated in FIG. 6, in the misting step S14, a liquid raw material is put into the second chamber 92 via the liquid supply nozzle 93. The ultrasonic wave generator 92A is driven to make the raw material into mist-like with ultrasonic waves. The term “mist-like” refers to a state in which droplets having a particle size of 10 μm or less are formed. The raw material include aluminum acetylacetonate, methanol, and water. That is, the raw material contains aluminum atoms and oxygen atoms. Further, the raw material contains carbon atoms and hydrogen atoms.

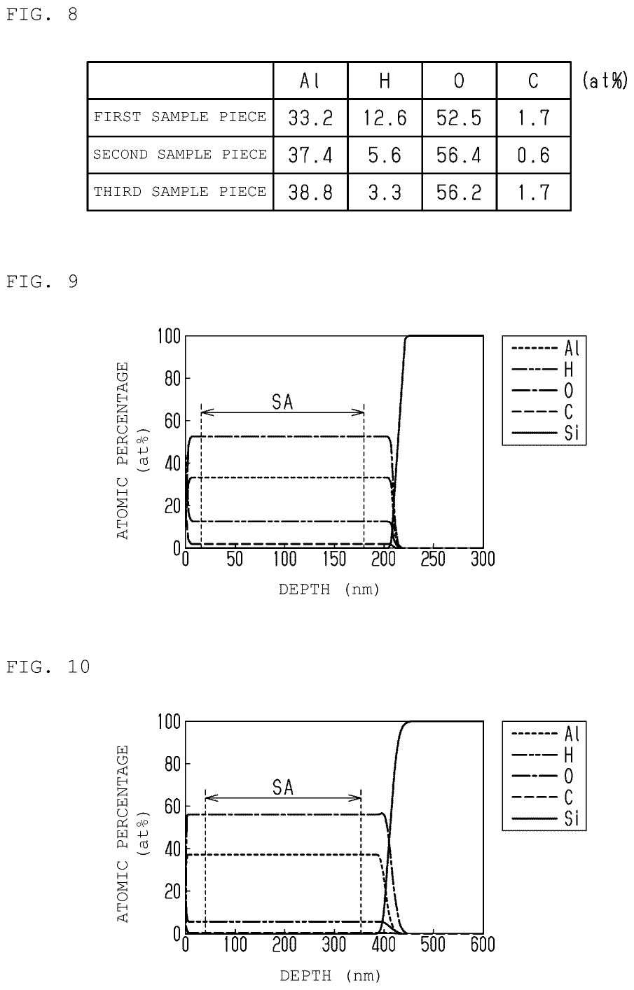

Next, as illustrated in FIG. 4, the supply step S15 is performed. As illustrated in FIG. 7, in the supply step S15, the carrier gas is supplied into the second chamber 92 via the gas supply nozzle 94. As a result, the mist-like raw material is supplied from the inside of the second chamber 92 into the first chamber 91 together with the carrier gas. The carrier gas is, for example, an inert gas such as oxygen, ozone, nitrogen, and argon. The carrier gas may be a reducing gas such as a hydrogen gas and a forming gas. The excess carrier gas and the excess raw material supplied into the first chamber 91 are discharged to the outside of the film forming apparatus 100 through the discharge passage 91C.

Next, as illustrated in FIG. 4, the heating step S16 is performed. In the heating step S16, the atmosphere in the first chamber 91 is heated while performing the supply step S15. Specifically, in the heating step S16, the heater 91A is driven to heat the atmosphere inside the first chamber 91. By heating, the particle size of the mist flowing into the first chamber 91 from the second chamber 92 is reduced. The temperature in the first chamber 91 at this time is, for example, several hundred degrees. During the heating step S16, the fine mist of the raw material adheres to the base body 20, whereby the alumina film 50 is formed on the outer surface 21 of the base body 20. In addition, the composition ratio of the atoms contained in the raw material is made constant during execution of the misting step S14, the supply step S15, and the heating step S16 described above. That is, the atomic composition ratio of the mist formed from the raw material is substantially the same in any time zone during the above steps. As such mist is deposited, the atomic percentage in the alumina film 50 becomes substantially constant over the entire alumina film 50. In particular, in the specific region SA excluding the boundaries with other objects in the alumina film 50, the atomic percentage of each atom is substantially constant. The steps from the charging step S13 to the heating step S16 are a film forming method for forming the alumina film 50 on the outer surface 21 of the base body 20.

Next, the conductor applying step S17 is performed. In the conductor applying step S17, the base body 20 on which the alumina film 50 has been formed is taken out from the film forming apparatus 100. A conductor paste is applied to two portions of the outer surface of the alumina film 50, that is, a portion including a portion covering the first end surface 22A of the base body 20 and a portion including a portion covering the second end surface 22B of the base body 20. Specifically, the conductor paste is applied to cover the alumina film 50 on the entire region of the first end surface 22A and a part of the four side surfaces 22C. Furthermore, the conductor paste is applied to cover the alumina film 50 on the entire region of the second end surface 22B and a part of the four side surfaces 22C.

Next, the hardening step S18 is performed. Specifically, in the hardening step S18, the base body 20 is heated. In the hardening step S18, the conductor paste applied in the conductor applying step S17 is fired to form the first underlying electrode 61A and the second underlying electrode 62A.

In the present exemplary embodiment, at the time of heating in the hardening step S18, palladium contained on the side with the first internal electrodes 41 is attracted toward the side with the first underlying electrode 61A containing copper by the Kirkendall effect caused from the difference in diffusion rate between the first internal electrodes 41 and the first underlying electrode 61A. As a result, the first penetrating portion 71 extends through the alumina film 50 from the first internal electrode 41 toward the first underlying electrode 61A. As a result, the first internal electrode 41 and the first underlying electrode 61A are connected. In this respect, the same applies to the second penetrating portion 72 connecting the second internal electrode 42 and the second underlying electrode 62A.

Next, the plating step S19 is performed. Parts of the first underlying electrode 61A and second underlying electrode 62A are subjected to electroplating. As a result, the first metal layer 61B is formed on the surface of the first underlying electrode 61A. In addition, the second metal layer 62B is formed on the surface of the second underlying electrode 62A. Although not illustrated, the first metal layer 61B and the second metal layer 62B are electroplated with two kinds, nickel and tin, to form a two-layer structure. In this way, the electronic component 10 is formed.

### <Atomic Percentage>

Here, alumina films 50 were produced with different film formation conditions, and the atomic percentage of each atom in each alumina film 50 was measured.

First, the alumina film 50 was formed on a silicon substrate by performing the misting step S14, the supply step S15, and the heating step S16 as described above. In addition, three sample pieces were produced by changing the temperature condition in the heating step S16. A first sample piece was produced by setting the heating time to 30 minutes and the heating temperature to 400 degrees in the heating step S16. A second sample piece was produced by setting the heating time to 30 minutes and the heating temperature to 500 degrees in the heating step S16. A third sample piece was formed by forming a film with a heating time of 30 minutes and a heating temperature of 400 degrees in the heating step S16, and then performing an annealing treatment in an atmosphere of 800 degrees.

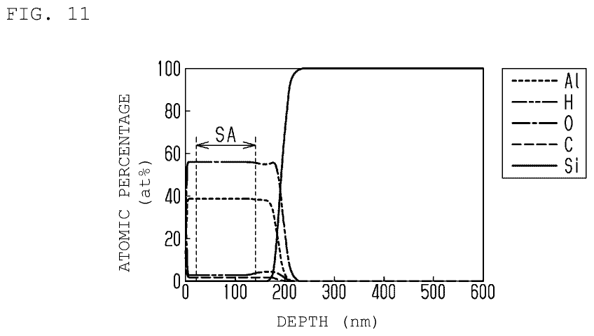

As shown in FIG. 9, composition analysis by RBS was performed on the first sample piece. The composition analysis was performed on a portion located in an arbitrary range of a diameter of 2 mm when the sample piece was viewed in a plan view in a direction orthogonal to the main surface of the silicon substrate. The 0 nm point in the measurement result indicates the position of the outer surface of the alumina film 50. In the first sample piece, silicon atoms increased in the vicinity of about 205 nm from the outer surface of the alumina film 50 to the silicon substrate side. That is, in the first sample piece, the boundary between the alumina film 50 and the silicon substrate is at a position of about 205 nm from the outer surface of the alumina film 50. In other words, the thickness of the alumina film 50 was about 205 nm. A region of the alumina film 50 of the first sample piece excluding a range of 20.5 nm from the boundary surface with the silicon substrate toward the outer surface of the alumina film 50 in the alumina film 50 and a range of 20.5 nm from the outer surface of the alumina film 50 toward the silicon substrate in the alumina film 50 is defined as the specific region SA. In this case, in the specific region SA, the atomic percentage of each atom included in the alumina film 50 is substantially constant. Specifically, as shown in FIG. 8, in the specific region SA, the atomic percentage of aluminum atoms was 33.2 at % and was substantially constant. In the specific region SA, the atomic percentage of oxygen atoms was 52.5 at % and was substantially constant. In the specific region SA, the atomic percentage of carbon atoms was 1.7 at % and was substantially constant. In the specific region SA, the atomic percentage of hydrogen atoms was 12.6 at % and was substantially constant.

As shown in FIG. 10, composition analysis by RBS was performed on the second sample piece. The measurement range was the same as that of the first sample piece. In the second sample piece, silicon atoms increased in the vicinity of about 390 nm from the outer surface of the alumina film 50. That is, in the second sample piece, the thickness of the alumina film 50 was about 390 nm. A region of the alumina film 50 of the second sample piece excluding a range of 39 nm from the boundary surface with the silicon substrate toward the outer surface of the alumina film 50 in the alumina film 50 and a range of 39 nm from the outer surface of the alumina film 50 toward the silicon substrate in the alumina film 50 is defined as the specific region SA. In this case, in the specific region SA, the atomic percentage of each atom included in the alumina film 50 is substantially constant. Specifically, as shown in FIG. 8, in the specific region SA, the atomic percentage of aluminum atoms was 37.4 at % and was substantially constant. In the specific region SA, the atomic percentage of oxygen atoms was 56.4 at % and was substantially constant. In the specific region SA, the atomic percentage of carbon atoms was 0.6 at % and was substantially constant. In the specific region SA, the atomic percentage of hydrogen atoms was 5.6 at % and was substantially constant.

As shown in FIG. 11, composition analysis by RBS was performed on the third sample piece. The measurement range was the same as that of the first sample piece. In the third sample piece, silicon atoms increased in the vicinity of about 180 nm from the outer surface of the alumina film 50. That is, in the third sample piece, the thickness of the alumina film 50 was about 180 nm. A region of the alumina film 50 of the third sample piece excluding a range of 18 nm from the boundary surface with the silicon substrate toward the outer surface of the alumina film 50 in the alumina film 50 and a range of 18 nm from the outer surface of the alumina film 50 toward the silicon substrate in the alumina film 50 is defined as the specific region SA. In this case, in the specific region SA, the atomic percentage of each atom included in the alumina film 50 was substantially constant, but in a certain region on the side close to the silicon substrate in the alumina film 50, there was a slight variation in the atomic percentage of each atom. However, also in this case, the variation in the atomic percentage of each atom was such a slight variation that the atomic percentage can be regarded as constant. As shown in FIG. 8, in the specific region SA, the atomic percentage of aluminum atoms was 38.8 at %. In the specific region SA, the atomic percentage of oxygen atoms was 56.2 at %. In the specific region SA, the atomic percentage of carbon atoms was 1.7 at %. In the specific region SA, the atomic percentage of hydrogen atoms was 3.3 at %.

Each region obtained by dividing the specific region SA into 10 equal parts in the thickness direction of the alumina film 50 is defined as a divided region. In this case, “the atomic percentage of carbon atoms is substantially constant in the specific region SA” means that the atomic percentage of specific atoms in each of the divided regions is 0.5 times or more and 1.5 times or less the atomic percentage of carbon atoms in the entire specific region SA. The same applies to “the atomic percentage of hydrogen atoms is substantially constant in the specific region SA”. In addition, “the atomic percentage of aluminum atoms is substantially constant in the specific region SA” means that the atomic percentage of aluminum atoms in each of the divided regions falls within the range of minus 5 at % or more and plus 5 at % or less the atomic percentage of aluminum atoms in the entire specific region SA. The same applies to “the atomic percentage of oxygen atoms is substantially constant in the specific region SA”.

### Advantageous Effects of Present Exemplary Embodiment

(1) According to the above exemplary embodiment, the alumina film 50 contains at least one of hydrogen atoms and carbon atoms. That is, the alumina film 50 of the above exemplary embodiment contains an organic component. Since the alumina film 50 contains such organic components, the alumina film 50 can secure adhesion between the first underlying electrode 61A and the second underlying electrode 62A, which are sintered bodies containing organic components.

In the above exemplary embodiment, the atomic percentage of carbon atoms in each of the divided regions is 0.5 times or more and 1.5 times or less the atomic percentage of carbon atoms in the entire specific region SA. That is, in the specific region SA, carbon atoms are located substantially uniformly without unevenness. If carbon atoms are concentrated in a part of the alumina film 50, cracks are likely to be formed at the portion in which carbon atoms are concentrated during manufacture due to a difference in thermal shrinkage ratio with other portions having different composition ratios. According to the configuration of the above exemplary embodiment, the possibility of formation of cracks can be suppressed. The atomic percentage of hydrogen atoms in each of the divided regions is 0.5 times or more and 1.5 times or less the atomic percentage of hydrogen atoms in the entire specific region SA. Therefore, as in the case of carbon atoms described above, it is possible to reduce the possibility of formation of cracks due to the unevenness of hydrogen atoms.

(2) In the above exemplary embodiment, at least 0.3 at % of carbon atoms are present in the specific region SA. Therefore, the effect of improving the adhesion to the first underlying electrode 61A and the second underlying electrode 62A containing organic substances can be reliably obtained. In the above exemplary embodiment, the content of carbon atoms in the specific region SA is 3.0 at % at most. That is, the amount of carbon atoms is not so large as compared with the ratio to the entire specific region SA. Therefore, it is possible to suppress deterioration of the barrier performance of the alumina film 50 due to excessive carbon atoms in the alumina film 50.

(3) In the above exemplary embodiment, at least 3.0 at % of hydrogen atoms are present in the specific region SA. Therefore, the effect of improving the adhesion to the first underlying electrode 61A and the second underlying electrode 62A containing organic substances can be reliably obtained. In the above exemplary embodiment, the content of hydrogen atoms in the specific region SA is 15.0 at % at most. That is, the amount of hydrogen atoms is not so large as compared with the ratio to the entire specific region SA. Therefore, it is possible to suppress deterioration of the barrier performance of the alumina film 50 due to excessive hydrogen atoms in the alumina film 50.

(4) In the above exemplary embodiment, the atomic percentage of aluminum atoms and the atomic percentage of oxygen atoms in each of the divided regions both fall within the range of minus 5 at % or more and plus 5 at % or less of the atomic percentage of the same kind of atoms in the entire specific region SA. As described above, since the alumina component is located substantially uniformly in the specific region SA, the barrier performance is secured over the entire region of the alumina film 50.

(5) In the exemplary embodiment mentioned above, the composition ratio of the atoms contained in the raw material is constant while the misting step S14, the supply step S15, and the heating step S16 are performed. In the alumina film 50 formed with the mist formed from such a raw material, specific atoms are less likely to be unevenly positioned. Therefore, with the above configuration, the effect of suppressing cracks as described in (1) can be more remarkably obtained.

### Modification Examples

The above-mentioned exemplary embodiment and the following modification examples can be implemented in combination within a range that is not technically contradictory.
In the above exemplary embodiment, the electronic component 10 is not limited to a negative characteristic thermistor component. For example, the electronic component 10 may be a piezoelectric component, a multilayer ceramic capacitor, an inductor, or the like.
In the exemplary embodiment mentioned above, the numbers of the first internal electrodes 41 and the second internal electrodes 42 are not limited to the example of the exemplary embodiment mentioned above. The number of the first internal electrodes 41 may be less than or more than two. In this respect, the same applies to the second internal electrodes 42.
In the exemplary embodiment mentioned above, the material of the first underlying electrode 61A and the material of the second underlying electrode 62A are not limited to the examples of the exemplary embodiment mentioned above. For example, the material of the first underlying electrode 61A and the material of the second underlying electrode 62A may be a mixture of silver and glass. The material of the first underlying electrode 61A and the material of the second underlying electrode 62A do not have to necessarily contain an organic component.
In the exemplary embodiment mentioned above, the alumina film 50 may not cover the entire base body 20. It is sufficient that the alumina film 50 covers at least a part of the outer surface 21 of the base body 20.
In the exemplary embodiment mentioned above, the average value of the thickness of the alumina film 50 is not limited to the example of the exemplary embodiment mentioned above. The average value of the thickness of the alumina film 50 may be an arbitrary thickness in consideration of stress and the like related to the alumina film 50.
In the above exemplary embodiment, the atomic percentage of each atom of the alumina film 50 is merely an example. It is sufficient that the main component of the alumina film 50 is an alumina component and that the atomic percentage of the specific atoms in each of the divided regions is 0.5 times or more and 1.5 times or less the atomic percentage of the same kind of specific atoms in the entire specific region SA.
In the above exemplary embodiment, as the atomic percentage of the divided region, the atomic percentage at a plurality of arbitrary points in the divided region may be measured, and the average of the measured values may be adopted.
In the above exemplary embodiment, it is sufficient that the alumina film 50 contains one or more selected from carbon atoms and hydrogen atoms as the specific atoms. That is, the alumina film 50 may be configured to contain only carbon atoms as the specific atoms or may be configured to contain only hydrogen atoms as the specific atoms.
In the exemplary embodiment mentioned above, the chemical substance of the raw material adopted in the misting step S14, the supply step S15, and the heating step S16 is not limited to the example in the exemplary embodiment mentioned above. For example, the raw material may be an organic salt, organic solvent, or the like containing aluminum. The raw material may or may not contain water.
In the exemplary embodiment mentioned above, the composition ratio of the atoms contained in the raw material may be changed during execution of the misting step S14, the supply step S15, and the heating step S16. However, also when the composition ratio of the raw material is changed, in the alumina film 50 to be formed, the atomic percentage of the specific atoms in each divided region must be 0.5 times or more and 1.5 times or less the atomic percentage of the same kind of specific atoms in the entire specific region SA.
In the above exemplary embodiment, the atomic percentage of carbon atoms in the entire specific region SA of the alumina film 50 may be less than 0.3 at %. The atomic percentage of carbon atoms in the entire specific region SA of the alumina film 50 may be more than 3.0 at %.
In the above exemplary embodiment, the atomic percentage of hydrogen atoms in the entire specific region SA of the alumina film 50 may be less than 3.0 at %. The atomic percentage of hydrogen atoms in the entire specific region of the alumina film 50 may be more than 15.0 at %.
In the above exemplary embodiment, the atomic percentage of aluminum atoms and the atomic percentage of oxygen atoms in each of the divided regions may both be less than minus 5 at % or more than plus 5 at % of the atomic percentage of the same kind of atoms in the entire specific region SA.

### <Supplementary Note>

Technical ideas that can be derived from the above exemplary embodiments and modification examples will be described below.
[1] An electronic component including: a base body; an alumina film covering an outer surface of the base body and containing an aluminum atom and an oxygen atom; an internal electrode located inside the base body; and an external electrode electrically connected to the internal electrode and located on an outer surface of the alumina film, in which the alumina film contains one or more specific atoms selected from a carbon atom and a hydrogen atom, and where a region of the alumina film excluding a range of 10% of a thickness of the alumina film from a boundary surface with the base body toward the outer surface of the alumina film and a range of 10% of the thickness of the alumina film from the outer surface of the alumina film toward the base body is defined as a specific region and each region obtained by dividing the specific region into 10 equal parts in a thickness direction of the alumina film is defined as a divided region, an atomic percentage of the specific atom in each divided region is 0.5 times or more and 1.5 times or less an atomic percentage of the specific atom of a same kind in the entire specific region.
[2] The electronic component according to [1], in which the alumina film contains the carbon atom as the specific atom, and an atomic percentage of the carbon atom in the entire specific region is 0.3 at % or more and 3.0 at % or less.
[3] The electronic component according to [1] or [2], in which the alumina film contains the hydrogen atom as the specific atom, and an atomic percentage of the hydrogen atom in the entire specific region is 3.0 at % or more and 15.0 at % or less.
[4] The electronic component according to any one of [1] to [3], in which an atomic percentage of the aluminum atom and an atomic percentage of the oxygen atom in each of the divided regions both fall within a range of minus 5 at % or more and plus 5 at % or less of an atomic percentage of a same kind of atom in the entire specific region.
[5] A film forming method for forming an alumina film on an outer surface of a base body, the film forming method including: a charging step of charging the base body into a first chamber that is capable of heating an internal atmosphere; a misting step of forming a raw material that is liquid and contains an aluminum atom and an oxygen atom into mist-like with an ultrasonic wave in a second chamber; a supply step of supplying the mist-like raw material from an inside of the second chamber into the first chamber together with a carrier gas; and a heating step of heating the atmosphere inside the first chamber while performing the supply step, in which the raw material further contains one or more selected from a carbon atom and a hydrogen atom.
[6] The film forming method according to [5], in which a composition ratio of atoms contained in the raw material is made constant during execution of the misting step, the supply step, and the heating step.

### DESCRIPTION OF REFERENCE SYMBOLS

SA: Specific region
10: Electronic component
20: Base body
21: Outer surface
41: First internal electrode
42: Second internal electrode
50: Alumina film
61: First external electrode
62: Second external electrode

1. An electronic component comprising:
a base body;
an alumina film covering an outer surface of the base body and containing an aluminum atom and an oxygen atom;
an internal electrode located inside the base body; and
an external electrode electrically connected to the internal electrode and located on an outer surface of the alumina film,
wherein the alumina film contains one or more specific atoms selected from a carbon atom and a hydrogen atom, and
where a region of the alumina film excluding a range of 10% of a thickness of the alumina film from a boundary surface with the base body toward the outer surface of the alumina film and a range of 10% of the thickness of the alumina film from the outer surface of the alumina film toward the base body is defined as a specific region and each region obtained by dividing the specific region into 10 equal parts in a thickness direction of the alumina film is defined as a divided region,
an atomic percentage (at %) of the specific atom in each divided region is 0.5 times or more and 1.5 times or less than an atomic percentage of the specific atom of a same kind in the entire specific region.

2. The electric component according to claim 1, wherein the thickness of alumina film is 150 nm to 400 nm.

3. The electronic component according to claim 1,
wherein the alumina film contains the carbon atom as the specific atom, and
an atomic percentage of the carbon atom in the entire specific region is 0.3 at % or more and 3.0 at % or less.

4. The electronic component according to claim 1,
wherein the alumina film contains the hydrogen atom as the specific atom, and
an atomic percentage of the hydrogen atom in the entire specific region is 3.0 at % or more and 15.0 at % or less.

5. The electronic component according to claim 1,
wherein an atomic percentage of the aluminum atom and an atomic percentage of the oxygen atom in each of the divided regions both fall within a range of minus 5 at % or more and plus 5 at % or less of an atomic percentage of a same kind of atom in the entire specific region.

6. The electronic component according to claim 3,
wherein a composition line of the aluminum atom, the oxygen atom and the carbon atom in composition analysis by RBS is parallel to the depth axis.

7. The electronic component according to claim 3,
wherein the Oxygen atoms, the aluminum atoms, and the carbon atoms contained in the film are larger in proportion in the order of oxygen, aluminum, and carbon.

8. The electric component according to claim 3,
wherein the ratio of the aluminum atom and the oxygen atom are decreased and the carbon atom is increased in the range of 10% of the thickness of the alumina film from the outer surface of the alumina film.

9. The electronic component according to claim 4,
wherein a composition line of the aluminum atom, the oxygen atom and the hydrogen atom in composition analysis by Rutherford backscattering spectrometry (RBS) is parallel to the depth axis.

10. The electronic component according to claim 4,
wherein the Oxygen atoms, the aluminum atoms, and the hydrogen atoms contained in the film are larger in proportion in the order of oxygen, aluminum, and carbon.

11. The electric component according to claim 4,
wherein the ratio of the aluminum atom and the oxygen atom are decreased and the hydrogen atom is increased in the range of 10% of the thickness of the alumina film from the outer surface of the alumina film.

12. The electronic component according to claim 1,
wherein the alumina film contains the carbon atom and hydrogen atom as the specific atom, and
an atomic percentage of the carbon atom in the entire specific region is 0.3 at % or more and 3.0 at % or less and an atomic percentage of the hydrogen atom in the entire specific region is 3.0 at % or more and 15.0 at % or less.

13. The electronic component according to claim 12,
wherein a composition line of the aluminum atom, the oxygen atom and the hydrogen atom in composition analysis by RBS is parallel to the depth axis.

14. The electronic component according to claim 12,
wherein the Oxygen atom, the aluminum atom, the carbon atom and the hydrogen atom contained in the film are larger in proportion in the order of oxygen, aluminum, hydrogen, and carbon.

15. The electric component according to claim 12,
wherein the ratio of the aluminum atom and the oxygen atom are decreased and the hydrogen atom and the carbon atom is increased in the range of 10% of the thickness of the alumina film from the outer surface of the alumina film.

16. A film forming method for forming an alumina film on an outer surface of a base body, the film forming method comprising:
charging the base body into a first chamber that is capable of heating an internal atmosphere;
forming a raw material that is liquid and contains an aluminum atom and an oxygen atom into mist-like with an ultrasonic wave in a second chamber;
supplying the mist-like raw material from an inside of the second chamber into the first chamber together with a carrier gas; and
heating the atmosphere inside the first chamber while performing the supply step,
wherein the raw material further contains one or more selected from a carbon atom and a hydrogen atom.

17. The film forming method according to claim 16,
wherein a composition ratio of atoms contained in the raw material is made constant during execution of the forming, the supplying, and the heating.
